(19) United States
(12) Patent Application Publication
(10) Pub. No.: US 2025/0140680 A1
(43) Pub. Date: May 1, 2025

(54) DISPLAY DEVICE AND METHOD OF MANUFACTURING THE SAME

(71) Applicant: Samsung Display Co., LTD., Yongin-si (KR)

(72) Inventors: KYUNGMIN CHOI, Yongin-si (KR); SUNGGUK AN, Yongin-si (KR)

(21) Appl. No.: 18/932,501

(22) Filed: Oct. 30, 2024

(30) Foreign Application Priority Data
Nov. 1, 2023 (KR) 10-2023-0149490

(51) Int. Cl. H01L 23/498; H01L 25/16; H01L 33/62

(52) U.S. Cl. CPC H01L 23/49838; H01L 25/167; H10H 20/857; H10H 20/0364

(57) ABSTRACT

A display device includes a display panel including a panel pad part. The display device includes a circuit board below the display panel and including a circuit pad part at least partially exposed from the display panel in a plan view. The display device includes a connection member which electrically connects the panel pad part and the circuit pad part.

This application claims priority to Korean Patent Application No. 10-2023-0149490, filed on Nov. 1, 2023, and all the benefits accruing therefrom under 35 U.S.C. § 119, the content of which in its entirety is herein incorporated by reference.

### BACKGROUND

### 1. Field

The disclosure relates to a display device. More specifically, the disclosure relates to a display device with a chip on film structure and a method of manufacturing the display device.

### 2. Description of the Related Art

Generally, a tiled display device may include a plurality of display devices for implementing a large screen. In some cases, a bezel located at a boundary between the display devices may be visible to the user, which may deteriorate a display quality of the tiled display device.

### SUMMARY

Embodiments provide a display device with improved display quality.

Embodiments provide a method for manufacturing the display device with improved display quality.

A display device according to an embodiment includes a display panel including a panel pad part, a circuit board below the display panel and including a circuit pad part, wherein the circuit pad part is at least partially exposed from the display panel in a plan view, and a connection member which electrically connects the panel pad part and the circuit pad part.

In an embodiment, one end of the connection member may be bonded to an upper surface of the panel pad part, and another end of the connection member may be bonded to an upper surface of a portion of the circuit pad part exposed from the display panel.

In an embodiment, the connection member may extend from the upper surface of the panel pad part to the upper surface of the circuit pad part along a side surface of the panel pad part.

In an embodiment, the side surface of the panel pad part may define a portion of an outline of the display panel in the plan view.

In an embodiment, the portion of the outline located on the circuit board may have a straight shape, a curved shape, a concave-convex shape, or a zigzag shape in a plan view.

In an embodiment, the connection member may be not disposed on a lower surface of the display panel.

In an embodiment, the connection member may include a conductive material.

In an embodiment, at least a portion of the circuit pad part may overlap the display panel in a plan view.

In an embodiment, the circuit pad part may be attached to a lower surface of the display panel.

In an embodiment, the circuit pad part may be located below the panel pad part.

In an embodiment, at least a portion of the circuit pad part may be exposed from the panel pad part in a plan view.

In an embodiment, at least a portion of the circuit pad part may overlap the panel pad part in a plan view.

In an embodiment, the display device may further include a protection member disposed on the connection member and covering at least a portion of the connection member.

In an embodiment, the circuit board may include a flexible film on which the circuit pad part is disposed and a driving chip mounted on the flexible film.

A method of manufacturing a display device according to an embodiment includes cutting a portion of a display panel including a panel pad part by irradiating the display panel with a laser based on a cutting line. The method includes forming a connection member having an end bonded to an upper surface of the panel pad part and another end bonded to an upper surface of a circuit pad part below the display panel, wherein the circuit pad part is at least partially exposed from the display panel.

In an embodiment, the cutting of the portion of the display panel may include cutting a portion of the panel pad part.

In an embodiment, at least a side surface of the panel pad part may be defined by the cutting of the portion of the panel pad part, and the forming of the connection member may include forming the connection member such that the connection member extends along the side surface of the panel pad part.

In an embodiment, the connection member may be formed of a conductive material.

In an embodiment, the method may further include attaching a circuit board including the circuit pad part to the display panel, below the display panel, and the attaching of the circuit board may be performed before the forming of the connection member.

In an embodiment, a portion of an outline located on the circuit board may have a straight shape, a curved shape, a concave-convex shape, or a zigzag shape in a plan view, wherein the portion of the outline corresponds to a portion of the cutting line.

The display device according to embodiments may include the circuit board disposed below the display panel. Accordingly, for example, a dead space of the display device may be reduced. In some aspects, embodiments of the present disclosure support preventing boundaries between adjacent display devices among the display devices included in a tiled display device from being visible from the outside or reducing sizes of the boundaries. Accordingly, for example, display quality of the tiled display device may be improved.

In some aspects, at least a portion of the circuit pad part of the circuit board may be exposed from the display panel (or the panel pad part of the display panel) in a plan view. Accordingly, for example, embodiments of the present disclosure support, even for cases in which the circuit board is located below the display panel, performing a front bonding process for the panel pad part and the circuit board. Therefore, embodiments of the present disclosure support implementing the display device without forming, in the display device, a separate configuration (for example, a hole penetrating a lower surface of the display panel, a conductive line mounted on the substrate, or the like) associated with bonding the panel pad part and the circuit board at a bottom of the display panel. Accordingly, for example, embodiments of the present disclosure support providing a display device having a simplified structure compared to some other display devices.

It is to be understood that both the foregoing general description and the following detailed description are examples and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a tiled display device according to an embodiment.

FIG. 2 is a block diagram illustrating a display device according to an embodiment.

FIG. 3 is a plan view illustrating a display device according to an embodiment.

FIG. 4 is a cross-sectional view taken along line I-I′ of FIG. 3.

FIG. 5 is an enlarged view of area A of FIG. 3 according to an embodiment.

FIG. 6 is a cross-sectional view taken along line II-II′ of FIG. 5 according to an embodiment.

FIG. 7 is a cross-sectional view taken along line II-II′ of FIG. 5 according to an embodiment.

FIG. 8 is an enlarged view of area B of FIG. 6.

FIG. 9 is a flowchart illustrating a method of manufacturing a display device according to an embodiment.

FIGS. 10 to 15 are views illustrating a method of manufacturing the display device of FIG. 9.

FIG. 16 is a flowchart illustrating a method of manufacturing a display device according to an embodiment.

FIGS. 17 to 20 are views illustrating a method of manufacturing the display device of FIG. 16.

FIG. 21 is an enlarged view of area A of FIG. 3 according to an embodiment.

FIG. 22 is a cross-sectional view taken along line III-III′ of FIG. 21.

FIGS. 23 to 26 are enlarged views of area A of FIG. 3 according to other embodiments.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

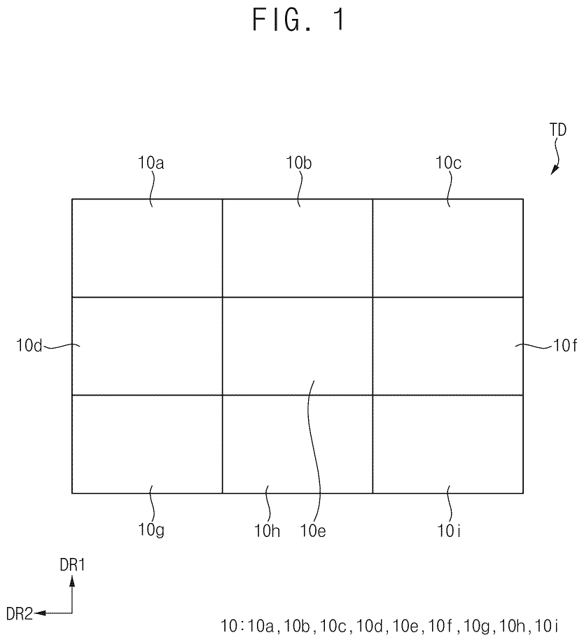

FIG. 1 is a plan view illustrating a tiled display device according to an embodiment.

Referring to FIG. 1, a display device according to an embodiment may be a tiled display device TD including a plurality of display devices 10 (e.g., first display device 10a through ninth display device 10i). The display devices 10 may display individual images or divide and display one image. The display devices 10 may include display panels of a same type, structure, size, or method, but are not limited thereto.

In an embodiment, the display devices 10 may be arranged in a matrix form along a first direction DR1 and a second direction DR2 intersecting the first direction DR1. For example, the second direction DR2 may be perpendicular to the first direction DR1. For example, as illustrated in FIG. 1, the tiled display device TD may include first to ninth display devices 10a to 10i arranged in a 3×3 shape in a plan view. The first to ninth display devices 10a to 10i may display first to ninth images, respectively. A user may watch an image combining the first to ninth images. However, embodiments supported by the present disclosure are not limited thereto, and the tiled display device TD may include 2 to 8 display devices 10, 10 or more display devices 10, or the like.

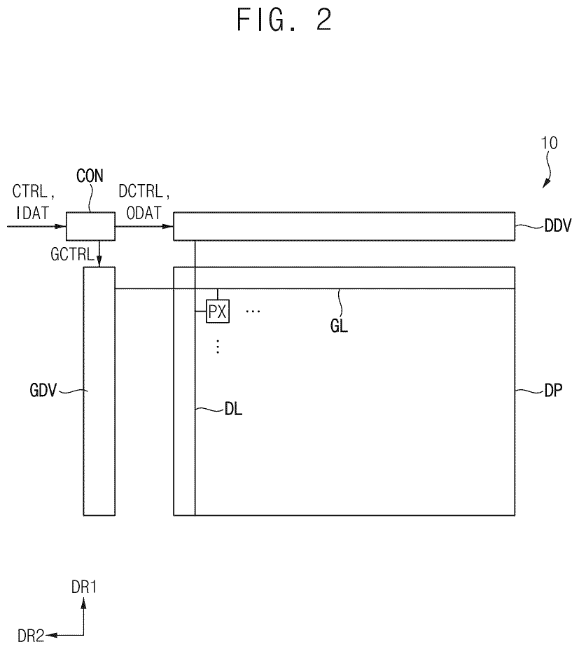

FIG. 2 is a block diagram illustrating a display device according to an embodiment. For example, the display device 10 of FIG. 2 may represent any one of the first to ninth display devices 10a to 10i of FIG. 1.

Referring to FIG. 2, the display device 10 may include a display panel DP and a driver. The driver may include a driving controller CON, a gate driver GDV, and a data driver DDV.

The display panel DP may include pixels PX, gate lines GL, and data lines DL. The pixels PX may be arranged in a display area where an image is displayed. The pixels PX may be electrically connected to the gate lines GL and data lines DL. For example, the pixels PX may be arranged in a matrix form along the first direction DR1 and the second direction DR2. Each of the pixels PX may include a transistor and a light emitting element. The light emitting element may generate light. The light emitting element may be an inorganic light emitting diode or an organic light emitting diode.

The gate lines GL and the data lines DL may intersect each other. For example, each of the gate lines GL may generally extend in the second direction DR2 and may be arranged along the first direction DR1. Each of the data lines DL may generally extend in the first direction DR1 and may be arranged along the second direction DR2.

The driving controller CON may generate a gate control signal GCTRL, a data control signal DCTRL, and an output image data ODAT based on input image data IDAT and an input control signal CTRL provided from an external device. For example, the input image data IDAT may be RGB data including red image data, green image data, and blue image data. The input control signal CTRL may include a master clock signal and an input data enable signal. The input control signal CTRL may further include a vertical synchronization signal and a horizontal synchronization signal.

The gate driver GDV may generate gate signals based on the gate control signal GCTRL provided from the driving controller CON. For example, the gate control signal GCTRL may include a vertical start signal and a gate clock signal. The gate driver GDV may sequentially output the gate signals to the gate lines GL of the display panel DP.

The data driver DDV may generate data signals based on the data control signal DCTRL and the output image data ODAT provided from the driving controller CON. For example, the data control signal DCTRL may include an output data enable signal, a horizontal start signal, and a load signal. The data driver DDV may output the data signals to the data lines DL of the display panel DP.

In an embodiment, the gate driver GDV and the data driver DDV may be implemented as an integrated circuit. The gate driver GDV and the data driver DDV may include an IC chip, a film on which the IC chip is mounted, and the like.

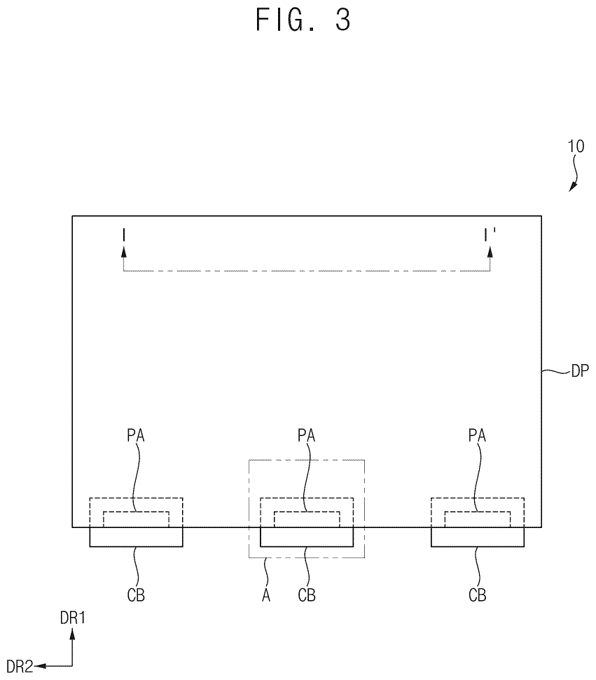

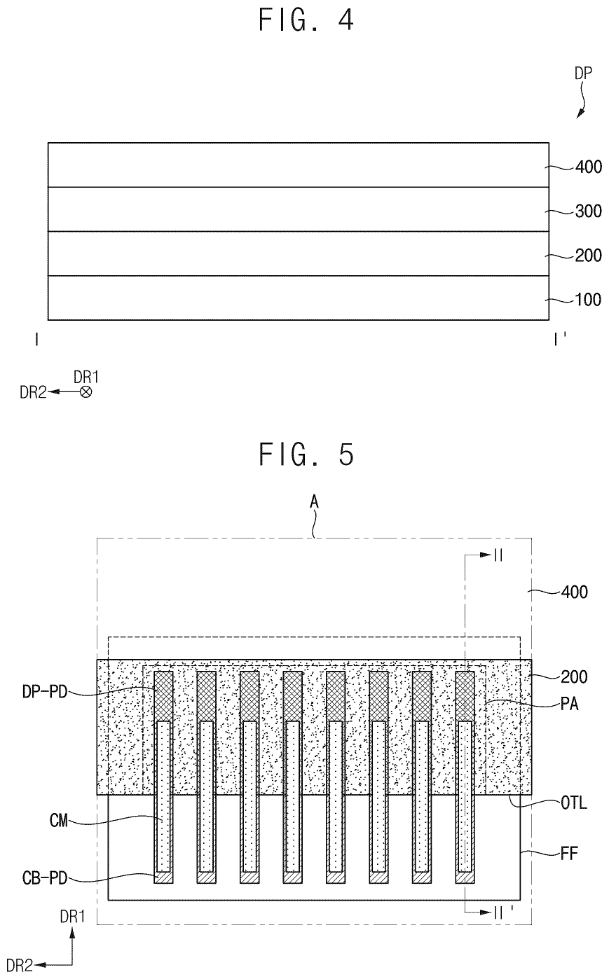

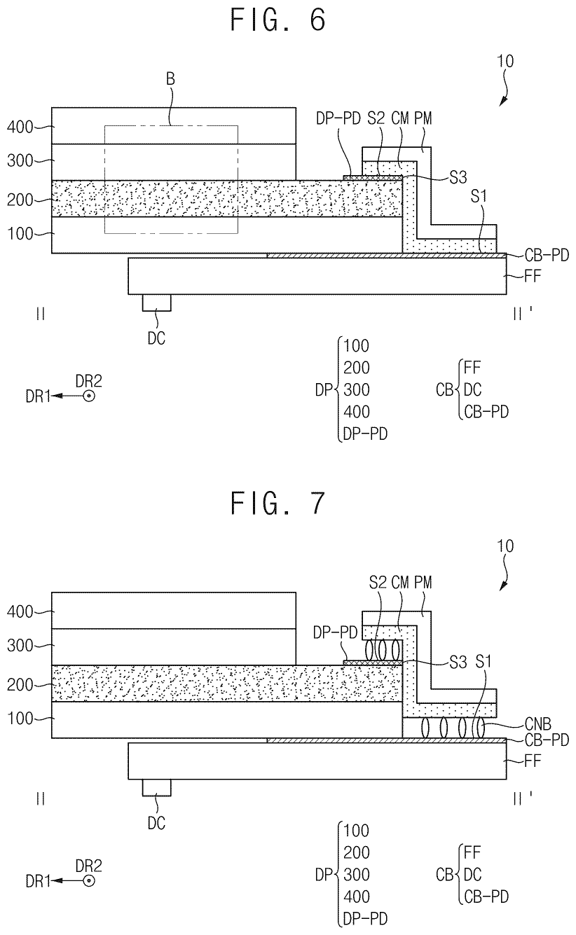

FIG. 3 is a plan view illustrating a display device according to an embodiment, FIG. 4 is a cross-sectional view taken along line I-I′ of FIG. 3, FIG. 5 is an enlarged view of area A of FIG. 3 according to an embodiment, and FIG. 6 is a cross-sectional view taken along line II-II′ of FIG. 5 according to an embodiment. For example, the display device 10 of FIG. 3 may represent any one of the first to ninth display devices 10a to 10i of FIG. 1.

Referring to FIGS. 3 to 6, the display device 10 according to an embodiment may include the display panel DP and a circuit board CB. In the example, the display device 10 is illustrated as including multiple circuit boards CB, but embodiments of the present disclosure are not limited thereto.

The display panel DP may include a substrate 100, a transistor layer 200, a light emitting element layer 300, and an encapsulation layer 400.

The substrate 100 may be a transparent insulating substrate. The substrate 100 may be formed of a flexible material, and at least a portion of the substrate 100 may be flexible and be bendable. In an example, the substrate 100 may have a multilayer structure including at least one organic layer and at least one inorganic layer. Examples of organic materials that can be used as the organic layer may include polyimide (PI), polyethersulfone (PES), polyacrylate (PAR), polyetherimide (PEI), polyethylene naphthalate (PEN), polyethylene terephthalate (PET), polyphenylene sulfide (PPS), polycarbonate (PC), cellulose acetate propionate (CAP), or the like. Examples of inorganic materials that can be used as the inorganic layer may include silicon oxide, silicon nitride, silicon oxynitride, or the like.

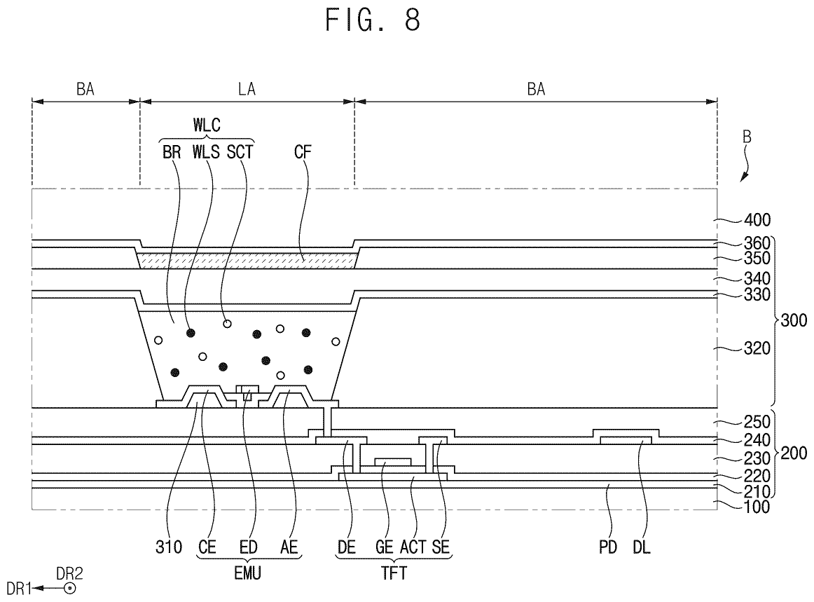

The transistor layer 200 may be disposed on the substrate 100. The transistor layer 200 may include at least one transistor. The light emitting element layer 300 may be disposed on the transistor layer 200. The light emitting element layer 300 may include at least one light emitting element electrically connected to the transistor. The encapsulation layer 400 may be disposed on the light emitting element layer 300. A detailed description of the transistor layer 200, the light emitting element layer 300, and the encapsulation layer 400 will be described later with reference to FIG. 8.

The display panel DP may further include a panel pad part DP-PD. The panel pad part DP-PD may be disposed in a pad area PA of the display panel DP. In an embodiment, the display panel DP may include a plurality of panel pad parts arranged along the second direction DR2. However, embodiments supported by the present disclosure are not necessarily limited thereto. The panel pad part DP-PD may be electrically connected to the transistor of the transistor layer 200. The panel pad part DP-PD may include a conductive material such as, for example, a metal.

The circuit board CB may be disposed below the display panel DP. For example, the circuit board CB may be attached (e.g. coupled) to a lower surface of the display panel DP such that the circuit board CB overlaps the pad area PA of the display panel DP. The circuit board CB may be electrically connected to the display panel DP.

In an example in which the circuit board CB is attached to the lower surface of the display panel DP, a width of an area of the circuit board CB which is exposed from the display panel DP in the first direction DR1 may be reduced in a plan view. For example, embodiments of the present disclosure support reducing the exposed area (e.g., in the first direction DR1 and the second direction DR2) of the circuit board CB. Accordingly, for example, embodiments of the present disclosure support preventing boundaries between adjacent display devices among the display devices 10a to 10i included in the tiled display device TD illustrated in FIG. 1 from being visible from the outside or reducing sizes of the boundaries. Accordingly, for example, display quality of the tiled display device TD may be improved.

The circuit board CB may include a flexible film FF, a driving chip DC, and a circuit pad part CB-PD.

In an embodiment, the circuit pad part CB-PD may refer to a circuit pad terminal. However, embodiments supported by the present disclosure are not necessarily limited thereto. For example, in an embodiment, the circuit pad part CB-PD may be interpreted to include the circuit pad terminal and a lead signal line connected to the circuit pad terminal.

The flexible film FF may include an insulating material. In an example, the flexible film FF may be formed of a flexible material, and at least a portion of the flexible film FF may be flexible and bendable. The circuit pad part CB-PD and the driving chip DC may be disposed on the flexible film FF.

The driving chip DC may be mounted on the flexible film FF. For example, the display device 10 may have a chip on film (COF) structure in which the driving chip DC is mounted on the flexible film FF and connected to the display panel DP through the flexible film FF. For example, the driving chip DC may be the driving controller CON, the gate driver GDV, or the data driver DDV of FIG. 2. However, embodiments supported by the present disclosure are not necessarily limited thereto.

In an embodiment, the circuit pad part CB-PD may be attached (e.g. coupled) to the lower surface of the display panel DP. For example, the circuit pad part CB-PD may be attached to the display panel DP through an adhesive member or the like. Examples of the adhesive member may include pressure sensitive adhesive (PSA), optical clear adhesive (OCA), optical clear resin (OCR), anisotropic conductive film (ACF), or the like. However, methods of attaching the display panel DP and the circuit pad part CB-PD in accordance with one or more embodiments of the present disclosure are not necessarily limited thereto.

In a plan view, at least a portion of the circuit pad part CB-PD may overlap the display panel DP. In some aspects, at least a portion of the circuit pad part CB-PD may be exposed from the display panel DP in a plan view. Specifically, for example, an upper surface S1 of the circuit pad part CB-PD may be exposed from the display panel DP.

The circuit pad part CB-PD may be disposed below the panel pad part DP-PD. In a plan view, at least a portion of the circuit pad part CB-PD may overlap the panel pad part DP-PD. In some aspects, in a plan view, at least a portion of the circuit pad part CB-PD may be exposed from the panel pad part DP-PD. Specifically, for example, in a plan view, the upper surface S1 of the circuit pad part CB-PD may be exposed from the panel pad part DP-PD. In FIG. 5, the portion of the circuit pad part CB-PD that overlaps the display panel DP and is obscured by the display panel DP is omitted from being illustrated.

The display device 10 may further include a connection member CM that electrically connects the panel pad part DP-PD and the circuit pad part CB-PD. For example, the panel pad part DP-PD and the circuit pad part CB-PD may be electrically and physically connected through the connection member CM.

In an embodiment, the display device 10 may include a plurality of connection members CM arranged along the second direction DR2. For example, the plurality of connection members CM may correspond to the plurality of panel pad parts DP-PD on a one-to-one basis. In some aspects, the plurality of connection members CM may correspond to the plurality of circuit pad parts CB-PD on a one-to-one basis. In other words, any one of the plurality of connection members CM may electrically connect a corresponding panel pad part DP-PD to a corresponding circuit pad part CB-PD. However, embodiments supported by the present disclosure are not necessarily limited thereto.

The connection member CM may include a conductive material such as, for example, a metal. For example, the connection member CM may be formed by pressing a conductive material on (or against) the panel pad part DP-PD and the circuit pad part CB-PD. In an embodiment, the connection member CM may be an anisotropic conductive film (ACF). However, embodiments supported by the present disclosure are not necessarily limited thereto.

In an embodiment, one end of the connection member CM may be bonded to an upper surface S2 of the panel pad part DP-PD, and another end of the connection member CM may be bonded to the upper surface S1 of the circuit pad part CB-PD. Specifically, for example, the other end of the connection member CM may be bonded to the upper surface S1 of the circuit pad part CB-PD exposed from the display panel DP. That is, in a plan view, at least a portion of the circuit pad part CB-PD may be exposed from the display panel DP, and the panel pad part DP-PD and the circuit pad part CB-PD may be electrically connected through the connection member CM located on a front of the panel pad part DP-PD and the circuit pad part CB-PD. In other words, as at least a portion of the circuit pad part CB-PD is exposed from the display panel DP in a plan view, embodiments of the present disclosure may support performing a front bonding process for the panel pad part DP-PD and the circuit board CB.

The connection member CM may extend along a side surface S3 of the panel pad part DP-PD. Specifically, for example, the connection member CM may extend from the upper surface S2 of the panel pad part DP-PD to the upper surface S1 of the circuit pad part CB-PD along the side surface S3 of the panel pad part DP-PD. In other words, the connection member CM may be disposed on the upper surface S2 of the panel pad part DP-PD, the side surface S3 of the panel pad part DP-PD, and the upper surface S1 of the circuit pad part CB-PD.

As illustrated in FIG. 6, in an embodiment, the connection member CM may contact the side surface S3 of the panel pad part DP-PD. However, embodiments supported by the present disclosure are not necessarily limited thereto, and the connection member CM may extend along the side surface S3 of the panel pad part DP-PD as being spaced apart from the side surface S3 of the panel pad part DP-PD at a predetermined interval.

In some embodiments, the connection member CM may be disposed such that the connection member CM is not on the lower surface of the display panel DP. For example, the connection member CM may not extend to the lower surface of the display panel DP. As described herein, as the front bonding process for the panel pad part DP-PD and the circuit board CB is performed, the connection member CM may be located in front of the panel pad part DP-PD and the circuit pad part CB-PD. Accordingly, for example, the connection member CM may be disposed such that the connection member CM is not on the lower surface of the display panel DP.

In the display device 10 according to an embodiment, the side surface S3 of the panel pad part DP-PD may define a portion of an outline OTL of the display panel DP in a plan view. For example, the outline OTL of the display panel DP may be a line defining a planar shape of the display panel DP. Specifically, for example, a cutting process of the display panel DP using a laser, which will be described later, may include cutting the panel pad part DP-PD to define the side surface S3 of the panel pad part DP-PD, such that the side surface S3 of the panel pad part DP-PD defines the portion of the outline OTL of the display panel DP in a plan view. Example aspects of the cutting process will be described in more detail later herein.

In some embodiments, the portion of the outline OTL located on the circuit board CB may have a straight shape in a plan view, but is not limited thereto. For example, the portion (or other portions) of the outline OTL may have a straight shape, a curved shape, a concave-convex shape, or a zigzag shape in a plan view. In some aspects, the portion of the outline OTL of the display panel DP may be defined by a side surface of the transistor layer 200 on the circuit board CB and the side surface S3 of the panel pad part DP-PD on the circuit board CB. Specifically, for example, the portion of the outline OTL located on the circuit board CB may correspond to a cutting line irradiated with a laser in the cutting process of the display panel DP using the laser, which will be described later. Example aspects of the cutting process, the cutting line, and the outline OTL will be described in more detail later herein.

In the display device 10 according to an embodiment, the circuit board CB may be disposed below the display panel DP. Accordingly, for example, a dead space of the display device 10 may be reduced. In some aspects, embodiments of the present disclosure support preventing boundaries between adjacent display devices among the display devices 10a to 10i included in the tiled display device TD illustrated in FIG. 1 from being visible from the outside or reducing sizes of the boundaries. Accordingly, for example, display quality of the tiled display device TD may be improved.

In some aspects, at least a portion of the circuit pad part CB-PD may be exposed from the display panel DP (or the panel pad part DP-PD) in a plan view. Accordingly, for example, even for cases in which the circuit board CB is located below the display panel DP, embodiments of the present disclosure may support performing the front bonding process for the panel pad part DP-PD and the circuit board CB. For example, the panel pad part DP-PD and the circuit pad part CB-PD may be electrically connected through the connection member CM located in front of the panel pad part DP-PD and the circuit pad part CB-PD. Therefore, embodiments of the present disclosure support implementing the display device 10 without forming, in the display device 10, a separate configuration (for example, a hole penetrating the lower surface of the display panel DP, a conductive line mounted on the substrate 100, or the like) associated with bonding the panel pad part DP-PD and the circuit board CB at a bottom of the display panel DP. Accordingly, for example, the structure of the display device 10 may be more simplified compared to some other display devices.

In an embodiment, the display device 10 may further include a protection member PM disposed on the connection member CM. The protection member PM may cover at least a portion of the connection member CM. For example, as illustrated in FIG. 6, the protection member PM may cover an upper surface of the connection member CM. In an embodiment, the protection member PM may entirely cover the connection member CM. The protection member PM may protect the connection member CM from moisture, oxygen, impurities, or external physical shock.

In an embodiment, the protection member PM may include an insulating material. For example, the protection member PM may include an organic material. Examples of the organic materials that can be used as the protection member PM may include photoresist, polyacryl-based resin, polyimide-based resin, siloxane-based resin, acryl-based resin, epoxy-based resin, or the like. Embodiments of the present disclosure support using the organic materials alone or in combination with each other. In some embodiments, the protection member PM may include an inorganic material.

In an embodiment, the protection member PM may include a light blocking material. Since the protection member PM includes a light blocking material, aspects of the protection member PM support preventing the connection member CM from being visible from the outside. In an example, the protection member PM may include a black pigment, a black dye, a carbon black, or the like.

In some embodiments, for convenience of explanation, the protection member PM is omitted in FIG. 5. In an embodiment, the protection member PM may be entirely disposed on the plurality of connection members illustrated in FIG. 5, but the embodiments supported by the present disclosure are not necessarily limited thereto.

FIG. 7 is a cross-sectional view taken along line II-II′ of FIG. 5 according to an embodiment. The cross-sectional view of FIG. 7 may correspond to the cross-sectional view of FIG. 6.

An embodiment of the display device 10 described with reference to FIG. 7 may be substantially the same as the embodiment of the display device 10 described with reference to FIG. 6. In some examples, the display device 10 described with reference to FIG. 7 may differ from the display device 10 described with reference to FIG. 6 in that the display device 10 described with reference to FIG. 7 includes a conductive ball CNB (or multiple conductive balls CNB). Accordingly, for example, descriptions of overlapping components may be replaced with the descriptions referring to FIGS. 3 to 6.

In an embodiment, the display device 10 may further include the conductive ball CNB. The conductive ball CNB may be disposed between the panel pad part DP-PD and the connection member CM and between the circuit pad part CB-PD and the connection member CM. For example, the panel pad part DP-PD and the one end of the connection member CM may be bonded through the conductive ball CNB, and the circuit pad part CB-PD and the other end of the connection member CM may be bonded through the conductive ball CNB.

FIG. 8 is an enlarged view of area B of FIG. 6.

Referring to FIGS. 6 and 8, in an embodiment, the transistor layer 200 may include a transistor TFT, a data line DL, a buffer layer 210, a gate insulating layer 220, an interlayer insulating layer 230, a first protective layer 240, and a first planarization layer 250. The transistor TFT may include an active layer ACT, a gate electrode GE, a source electrode SE, and a drain electrode DE.

The buffer layer 210 may be disposed on the substrate 100. The buffer layer 210 may include an inorganic insulating material. The buffer layer 210 may prevent impurities from diffusing from the substrate 100 into the active layer ACT.

The active layer ACT may be disposed on the buffer layer 210. In an example, the active layer ACT may include a silicon semiconductor, an oxide semiconductor, or the like. The silicon semiconductor may include amorphous silicon, polycrystalline silicon, or the like. The active layer ACT may include a source region, a drain region, and a channel region. The source region and the drain region may be doped with impurities. The channel region may be disposed between the source region and the drain region.

The gate insulating layer 220 may be disposed on the buffer layer 210. The gate insulating layer 220 may cover the active layer ACT. The gate insulating layer 220 may include an inorganic insulating material.

The gate electrode GE may be disposed on the gate insulating layer 220. The gate electrode GE may overlap the channel region of the active layer ACT. The gate electrode GE may include metal, alloy, conductive metal oxide, conductive metal nitride, transparent conductive material, or the like.

The interlayer insulating layer 230 may be disposed on the gate insulating layer 220. The interlayer insulating layer 230 may cover the gate electrode GE. The interlayer insulating layer 230 may include an inorganic insulating material.

The source electrode SE and drain electrode DE may be disposed on the interlayer insulating layer 230. The source electrode SE and the drain electrode DE may be connected to the source region and the drain region of the active layer ACT, respectively, through contact holes. The source electrode SE and the drain electrode DE may include metal, alloy, conductive metal oxide, conductive metal nitride, transparent conductive material, or the like.

The data line DL may be disposed on the interlayer insulating layer 230. The data line DL may include metal, alloy, conductive metal oxide, conductive metal nitride, transparent conductive material, or the like. The data line DL may be electrically connected to the panel pad part DP-PD. The data line DL may receive the data signal through the panel pad part DP-PD. For example, the data line DL may be electrically connected to the source electrode SE and may transmit the data signal to the source electrode SE.

In some embodiments, an example in which the data line DL is electrically connected to the panel pad part DP-PD is described, but the embodiments supported by the present disclosure are not limited thereto. For example, the gate line, a power transmission line, an initialization voltage line, or other data line, power line, or voltage line may be electrically connected to the panel pad part DP-PD. The gate line, the power transmission line, the initialization voltage line, or other data line, power line, or voltage line may be located on the buffer layer 210, the gate insulating layer 220, or the interlayer insulating layer 230.

The first protective layer 240 may cover the transistor TFT. The first protective layer 240 may protect the transistor TFT.

The first planarization layer 250 may be disposed on the first protective layer 240. The first planarization layer 250 may have a substantially flat upper surface without creating a step (also referred to herein as a stepped portion) around the transistor TFT. The first planarization layer 250 may include an organic insulating material.

The light emitting element layer 300 may be disposed on the transistor layer 200. In an embodiment, the light emitting element layer 300 may include an light emitting unit EMU, a first bank 310, a second bank 320, a wavelength converter WLC, a second protective layer 330, a second planarization layer 340, a light blocking layer 350, a color filter layer CF, and a third protective layer 360. The light emitting unit EMU may include a first electrode AE, a second electrode CE, and a light emitting element ED. Although one light-emitting area LA is illustrated in FIG. 8, embodiments of the present disclosure are not limited thereto, and the display device 10 may include first to third light-emitting areas which are repeatedly arranged. The first to third light-emitting areas may each emit light having of a different color. For example, the first light-emitting area may emit red light, the second light-emitting area may emit green light, and the third light-emitting area may emit blue light. In some aspects, in FIG. 8, for convenience, the light blocking area BA is illustrated as having a relatively wide width. However, the light blocking area BA may also have a relatively narrow width.

The first bank 310 and the second bank 320 may be disposed on the first planarization layer 250. The second bank 320 may have openings that expose the light emitting area LA. For example, the second bank 320 may surround the light emitting area LA in a plan view. That is, the light emitting area LA may be defined by the second bank 320. The second bank 320 may include an organic insulating material. The second bank 320 may further include a light blocking material to prevent color mixing between adjacent light emitting areas.

The first bank 310 (or multiple first banks 310, as illustrated at FIG. 8) may be disposed in the openings of the second bank 320. That is, the first bank 310 may overlap the light emitting area LA. The first bank 310 and the second bank 320 may each include an organic insulating material.

The first electrode AE may be disposed on the first planarization layer 250. The first electrode AE may overlap the light emitting area LA and may cover the first bank 310. The first electrode AE may be electrically connected to the drain electrode DE through a contact hole formed in the first protective layer 240 and the first planarization layer 250.

The second electrode CE may be disposed on the first planarization layer 250. The second electrode CE may overlap the light emitting area LA and may cover the first bank 310. For example, the second electrode CE may receive a common voltage supplied to the pixels. The first electrode AE and the second electrode CE may be insulated from each other by an insulating layer covering a portion of the first electrode AE and a portion of the second electrode CE that are adjacent to each other.

The light emitting element ED may be disposed between the first electrode AE and the second electrode CE on the first planarization layer 250. The light emitting element ED may be disposed on the insulating layer. One end of the light emitting element ED may be connected to the first electrode AE, and another end of the light emitting element ED may be connected to the second electrode CE. In an example, the light emitting element ED may include an active layer and emit light in the same wavelength range or light of the same color. For example, the light emitting element ED may emit blue light with a peak wavelength ranging from about 440 nm to about 480 nm.

In an example in which the light emitting area LA is the first light emitting area or the second light emitting area (for example, the light emitting area LA emits red light or green light), the wavelength converter WLC may be disposed on the light emitting unit EMU. The wavelength converter WLC may be surrounded by the second bank 320. The wavelength converter WLC may include a base resin BR, a scatterer SCT, and a wavelength shifter WLS.

The base resin BR may include a material with relatively high light transmittance. The base resin BR may be formed of a transparent organic material. In an example, the base resin BR may include at least one of organic materials such as, for example, epoxy resin, acrylic resin, cardo resin, imide resin, or the like.

The scatterer SCT may have a different refractive index from the base resin BR and may form an optical interface with the base resin BR.

The wavelength shifter WLS may convert or shift a peak wavelength of incident light. For example, the wavelength shifter WLS may convert blue light into red light or green light and emit the red light or the green light. The wavelength shifter WLS may include quantum dots, quantum rods, or phosphors. The quantum dots may be particulate materials that emit light of a specific color as electrons transition from a conduction band to a valence band.

A light emitted by the wavelength shifter WLS may have a full width of half maximum (FWHM) of an emission wavelength spectrum of about 45 nm or less, about 40 nm or less, or about 30 nm or less. Accordingly, for example, color reproducibility of the display device 10 may be improved.

When the light-emitting area LA is the third light-emitting area (for example, when the light-emitting area LA emits blue light), a transmission part may be disposed on the light emitting unit EMU. The transmission part may be surrounded by the second bank 320. The transmission part may include the base resin BR and the scatterer SCT, and in some aspects, may not include the wavelength shifter WLS. The transmission part may transmit blue light emitted from the light emitting unit EMU without converting the wavelength.

The second protective layer 330 may cover the wavelength converter WLC and the second bank 320. The second protective layer 330 may protect the wavelength converter WLC and the second bank 320.

The second planarization layer 340 may be disposed on the second protective layer 330. The second planarization layer 340 may have a substantially flat upper surface without creating a step around the wavelength converter WLC. The second planarization layer 340 may include an organic insulating material.

The light blocking layer 350 may be disposed on the second planarization layer 340. The light blocking layer 350 may overlap the second bank 320. The light blocking layer 350 may have an opening that overlaps the light emitting area LA.

The color filter layer CF may be disposed in the light emitting area LA on the second planarization layer 340. The color filter layer CF may be disposed in the opening of the light blocking layer 350. For example, the color filter layer CF may be surrounded by the light blocking layer 350 in a plan view. The color filter layer CF may selectively transmit light having a specific color and block or absorb light having a color different from the specific color.

The third protective layer 360 may cover the color filter layer CF and the light blocking layer 350. The third protective layer 360 may protect the color filter layer CF and the light blocking layer 350.

The encapsulation layer 400 may be disposed on the third protective layer 360. For example, the encapsulation layer 400 may include at least one inorganic layer and at least one organic layer.

In the display device 10 according to an embodiment, the circuit board CB may be disposed below the display panel DP. Accordingly, for example, a dead space of the display device 10 may be reduced. In some aspects, embodiments of the present disclosure support preventing boundaries between adjacent display devices among the display devices 10a to 10i included in the tiled display device TD illustrated in FIG. 1 from being visible from the outside or reducing sizes of the boundaries. Accordingly, for example, display quality of the tiled display device TD may be improved.

In some aspects, at least a portion of the circuit pad part CB-PD may be exposed from the display panel DP (or the panel pad part DP-PD) in a plan view. Accordingly, for example, even for cases in which the circuit board CB is located below the display panel DP, embodiments of the present disclosure support performing the front bonding process for the panel pad part DP-PD and the circuit board CB. For example, the panel pad part DP-PD and the circuit pad part CB-PD may be electrically connected through the connection member CM located in front of the panel pad part DP-PD and the circuit pad part CB-PD. Therefore, embodiments of the present disclosure support implementing the display device 10 without forming, in the display device 10, a separate configuration (for example, a hole penetrating the lower surface of the display panel DP, a conductive line mounted on the substrate 100, or the like) associated with bonding the panel pad part DP-PD and the circuit board CB at a bottom of the display panel DP. Accordingly, for example, a structure of the display device 10 may be more simplified compared to some other display devices.

In the descriptions of the methods and processes herein, the operations may be performed in a different order than the order illustrated and/or described, or the operations may be performed in different orders or at different times. Certain operations may also be left out of the methods and processes, one or more operations may be repeated, or other operations may be added. Descriptions that an element “may be disposed,” “may be formed,” “may be cut,” “may be pressed,” and the like include methods, processes, and techniques for disposing, forming, positioning, pressing, and modifying the element, and the like in accordance with example aspects described herein.

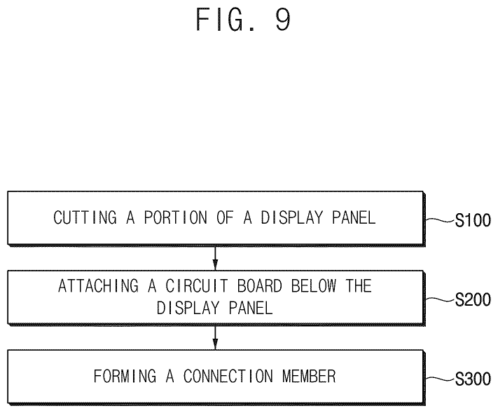

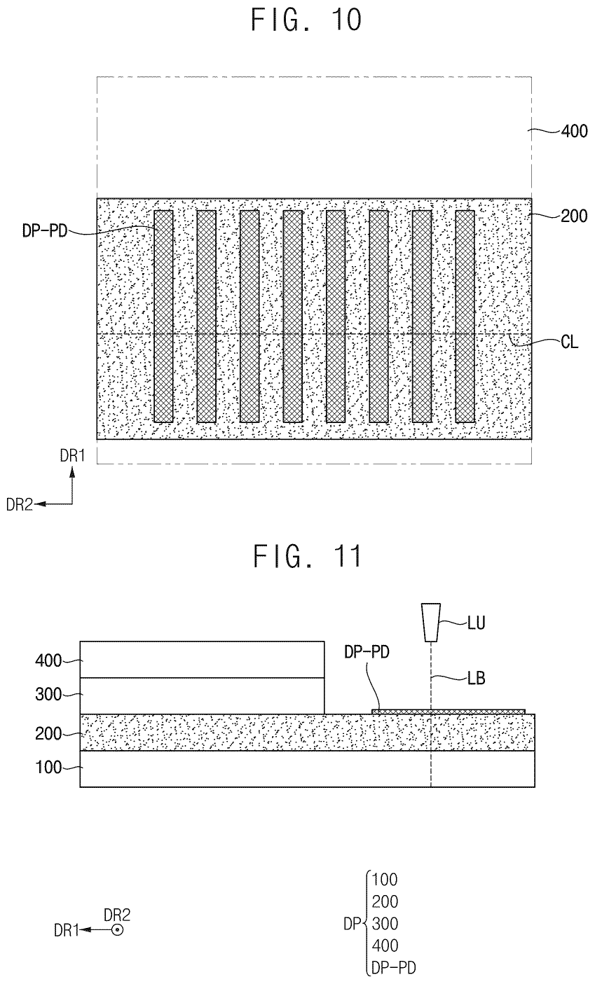

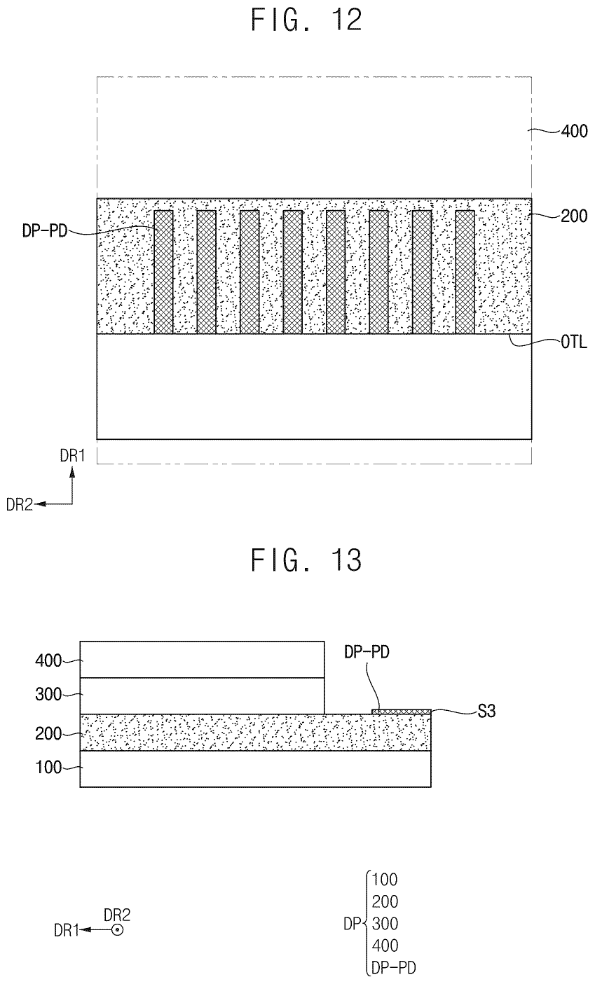

FIG. 9 is a flowchart illustrating a method of manufacturing a display device according one or more embodiments of the present disclosure. FIGS. 10 to 15 are views illustrating a method of manufacturing the display device of FIG. 9 in accordance with one or more embodiments of the present disclosure.

In an example, the method of manufacturing the display device described with reference to FIGS. 9 to 15 may include aspects of an embodiment of a method of manufacturing the display device 10 described with reference to FIGS. 3 to 6. Therefore, detailed description of overlapping components will be omitted.

Referring to FIG. 9, the method of manufacturing the display device 10 according to an embodiment may include cutting a portion of a display panel (S100), attaching a circuit board below the display panel (S200), and forming a connection member (S300).

Aspects of S100 are described with reference to FIGS. 10 to 13.

Referring to FIGS. 10 to 13, the method may include cutting the portion of the display panel DP by irradiating the display panel DP with a laser LB provided from a laser unit LU. The method may include irradiating the display panel DP with the laser LB, along a cutting line CL. Descriptions herein of irradiating an element (e.g., display panel DP) include emitting the laser LB by the laser unit LU, such that the laser LB is incident one or more portions of the element.

The cutting line CL may pass through one or more of the panel pad parts DP-PD. For example, the cutting line CL may pass through each of the panel pad parts DP-PD. Descriptions herein with respect to a panel pad part DP-PD may be implemented with respect to multiple panel pad parts DP-PD. That is, the cutting the portion of the display panel DP (S100) may include cutting a portion of the panel pad part DP-PD. Specifically, for example, the method may include cutting a portion of each of the substrate 100, the transistor layer 200, and the panel pad part DP-PD by irradiating the cutting line CL with the laser LB (e.g., irradiating one or more regions according to the cutting line CL). Accordingly, for example, cutting the portion of the display panel DP-PD may define the side surface S3 of the panel pad part DP-PD. Accordingly, for example, the side surface S3 of the panel pad part DP-PD may define the portion of the outline OTL of the display panel DP in a plan view.

In an embodiment, the cutting line CL may have a straight shape in a plan view. However, embodiments supported by the present disclosure are not necessarily limited thereto. For example, one or more portions of the cutting line CL may have a straight shape, a curved shape, a concave-convex shape, or a zigzag shape in a plan view.

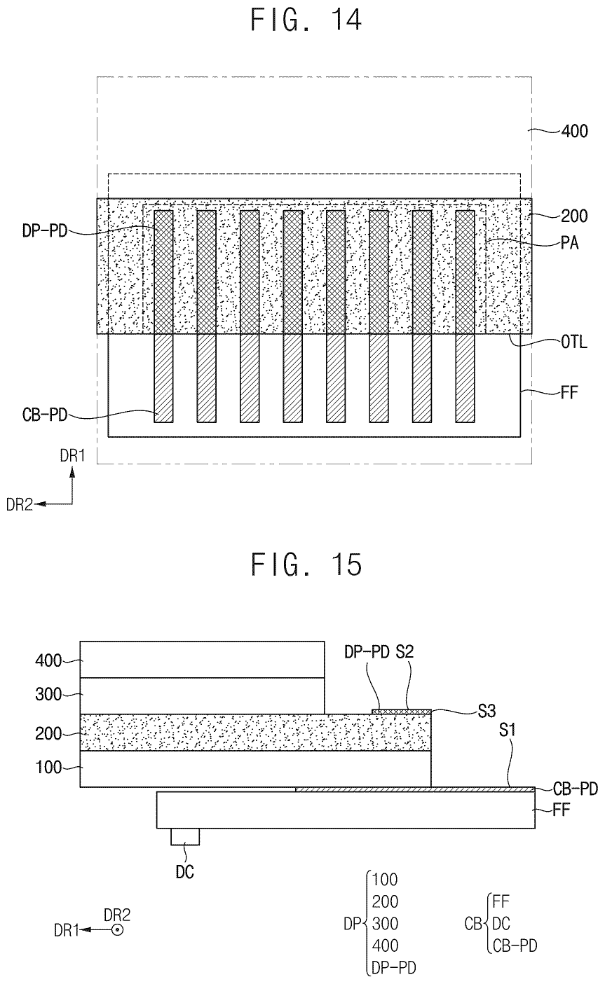

Aspects of S200 are described with reference to FIGS. 14 to 15.

Referring to FIGS. 14 and 15, the method may include attaching the circuit board CB to the display panel DP which is cut, below the display panel DP. For example, the circuit pad part CB-PD may be attached to the lower surface of the display panel DP. The circuit pad part CB-PD may be attached to the display panel DP by pressure sensitive adhesive (PSA), optical clear adhesive (OCA), optical clear resin (OCR), anisotropic conductive film (ACF), or the like, but the embodiments supported by the present disclosure are not necessarily limited thereto.

The method may include attaching the circuit board CB to the display panel DP such that at least a portion of the circuit pad part CB-PD is exposed from the display panel DP in a plan view. Specifically, for example, the circuit board CB may be attached to the display panel DP such that at least a portion of the circuit pad part CB-PD is exposed from the panel pad part DP-PD in a plan view. Accordingly, for example, in association with attaching the circuit board CB to the display panel DP (e.g., in a state in which the circuit board CB is attached to the display panel DP), the upper surface S1 of the circuit pad part CB-PD may be exposed from the panel pad part DP-PD in a plan view.

Thereafter, with reference to S300 of FIG. 9 and as illustrated in FIGS. 5 and 6, the method may include pressing a conductive material on (or against) the panel pad part DP-PD and the circuit pad part CB-PD to form the connection member CM. Accordingly, for example, the connection member CM may electrically connect the panel pad part DP-PD and the circuit pad part CB-PD.

The method may include bonding the one end of the connection member CM to the upper surface S2 of the panel pad part DP-PD, and the method may include bonding the other end of the connection member CM to the upper surface S1 of the circuit pad part CB-PD. Specifically, for example, the method may include bonding the other end of the connection member CM to the upper surface S1 of the circuit pad part CB-PD exposed from the display panel DP. That is, as at least a portion of the circuit pad part CB-PD is exposed from the display panel DP in a plan view, the method may include performing a front bonding process in association with bonding the panel pad part DP-PD and the circuit board CB.

The method may include forming the connection member CM such that the connection member CM extends along the side surface S3 of the panel pad part DP-PD. Specifically, for example, the connection member CM may extend from the upper surface S2 of the panel pad part DP-PD to the upper surface S1 of the circuit pad part CB-PD along the side surface S3 of the panel pad part DP-PD.

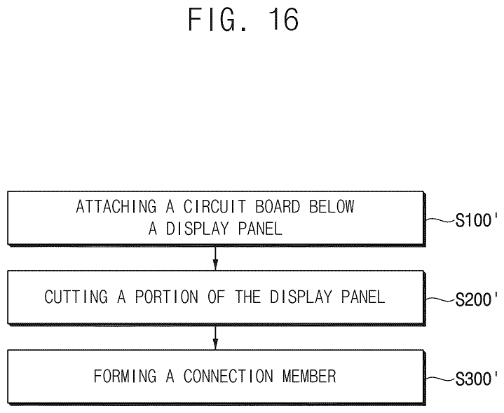

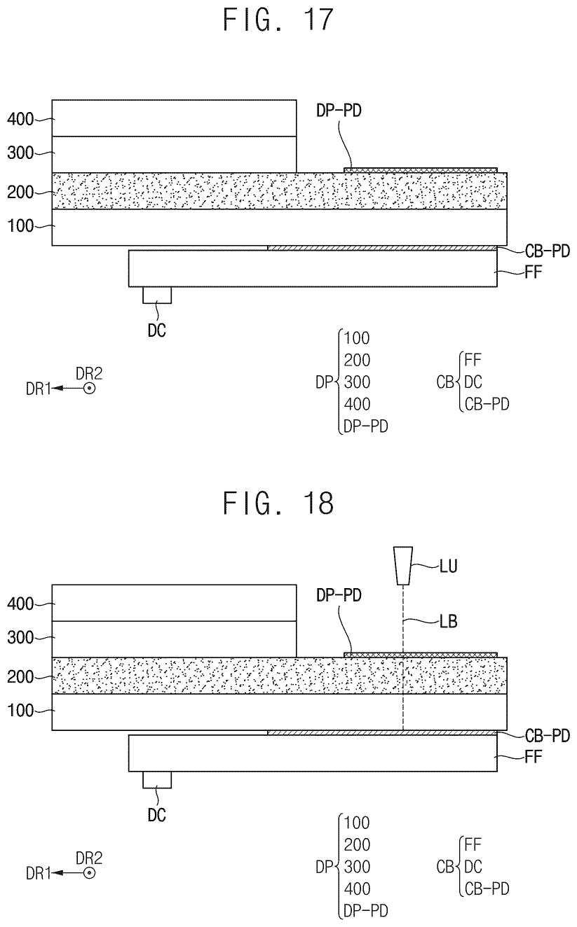

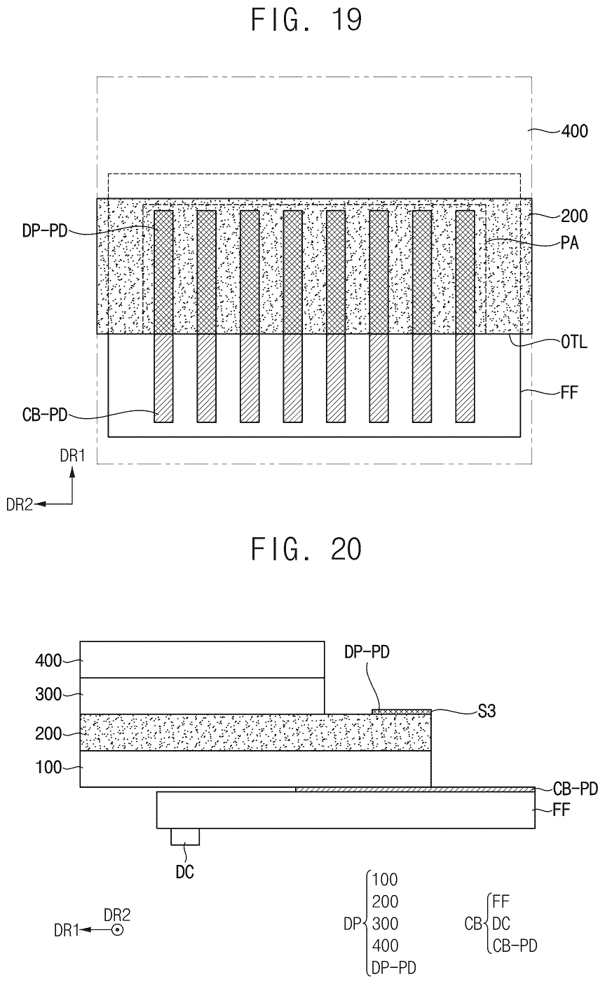

FIG. 16 is a flowchart illustrating a method of manufacturing a display device according to an embodiment. FIGS. 17 to 20 are views illustrating a method of manufacturing the display device of FIG. 16 in accordance with one or more embodiments of the present disclosure.

In an example, the method of manufacturing the display device described with reference to FIGS. 16 to 20 may include aspects of an embodiment of a method of manufacturing the display device 10 described with reference to FIGS. 3 to 6. Therefore, detailed description of overlapping components will be omitted.

In some aspects, the method of manufacturing the display device described with reference to FIGS. 16 to 20 may be the same as or similar to the method of manufacturing the displaying device with reference to FIGS. 9 to 15. In some examples, the method described with reference to FIGS. 16 to 20 may differ from the method described with reference to FIGS. 9 to 15 in that the method described with reference to FIGS. 16 to 20 may include performing a process of attaching the circuit board CB below the display panel DP before cutting a portion of the display panel DP. Accordingly, for example, descriptions of overlapping content may be replaced with the descriptions referring to FIGS. 9 to 15.

Referring to FIG. 16, the method of manufacturing the display device 10 according to an embodiment may include attaching a circuit board below the display panel (S100′), cutting a portion of the display panel (S200′), and forming a connection member (S300′).

Referring to FIG. 17, the method may include attaching the circuit board CB below the display panel DP which is cut. For example, the circuit pad part CB-PD may be attached to the lower surface of the display panel DP. The circuit pad part CB-PD may be attached to the display panel DP by pressure sensitive adhesive (PSA), optical clear adhesive (OCA), optical clear resin (OCR), anisotropic conductive film (ACF), or the like, but the embodiments supported by the present disclosure are not necessarily limited thereto.

Referring to FIGS. 18 and 19, the method may include cutting the portion of the display panel DP by irradiating the display panel DP with the laser LB provided from the laser unit LU. The method may include irradiating the display panel DP with the laser LB, along the cutting line CL.

The cutting line CL may pass through one or more of the panel pad parts DP-PD. For example, the cutting line CL may pass through each of the panel pad parts DP-PD. Descriptions herein with respect to a panel pad part DP-PD may be implemented with respect to multiple panel pad parts DP-PD. That is, cutting the portion of the display panel DP (S200′) may include cutting a portion of the panel pad part DP-PD. Specifically, for example, the method may include cutting a portion of each of the substrate 100, the transistor layer 200, and the panel pad part DP-PD by irradiating the cutting line CL with the laser LB. Accordingly, for example, cutting the portion of the display panel DP-PD may define the side surface S3 of the panel pad part DP-PD. Accordingly, for example, the side surface S3 of the panel pad part DP-PD may define the portion of the outline OTL of the display panel DP in a plan view.

In an embodiment, the cutting line CL may have a straight shape in a plan view. However, embodiments supported by the present disclosure are not necessarily limited thereto.

By cutting the portion of the display panel DP, at least a portion of the circuit pad part CB-PD may be exposed from the display panel DP in a plan view. Specifically, for example, the portion of the panel pad part DP-PD may be cut such that at least the portion of the circuit pad part CB-PD is exposed from the panel pad part DP-PD in a plan view. Accordingly, for example, in association with cutting the portion of the display panel DP (e.g., as a result of cutting the portion of the display panel DP), the upper surface S1 of the circuit pad part CB-PD may be exposed from the panel pad part DP-PD in a plan view.

Thereafter, with reference to S300′ of FIG. 16 and as illustrated in FIGS. 5 and 6, the method may include pressing a conductive material on (or against) the panel pad part DP-PD and the circuit pad part CB-PD to form the connection member CM. Accordingly, for example, the panel pad part DP-PD and the circuit pad part CB-PD may be electrically connected. The forming of the connection member CM (S300′) may be substantially the same as the forming of the connection member CM (S300) in the method of manufacturing the display device described with reference to FIGS. 9 to 15.

In the method of manufacturing the display device 10 according to an embodiment, the method may include cutting a portion of the panel pad part DP-PD cutting a portion of the display panel DP by a laser (e.g., using laser LB). Accordingly, for example, even if the circuit board CB is located below the display panel DP, at least a portion of the circuit pad part CB-PD may be exposed from the display panel DP (or the panel pad part DP-PD). Accordingly, for example, the method may include performing a front bonding process in association with bonding the panel pad part DP-PD and the circuit board CB. For example, the method may include electrically connecting the panel pad part DP-PD and the circuit pad part CB-PD by forming the connection member CM, in which one end of the connection member CM is bonded to the upper surface of the panel pad part DP-PD and another end of the connection member CM is bonded to the upper surface of the circuit pad part CB-PD. Accordingly, for example, embodiments of the present disclosure support implementing the display device 10 without implementing a separate process for bonding the panel pad part DP-PD and the circuit board CB at a bottom of the display panel DP. Accordingly, for example, a manufacturing process of the display device 10 may be more simplified compared to some other processes for manufacturing a display device.

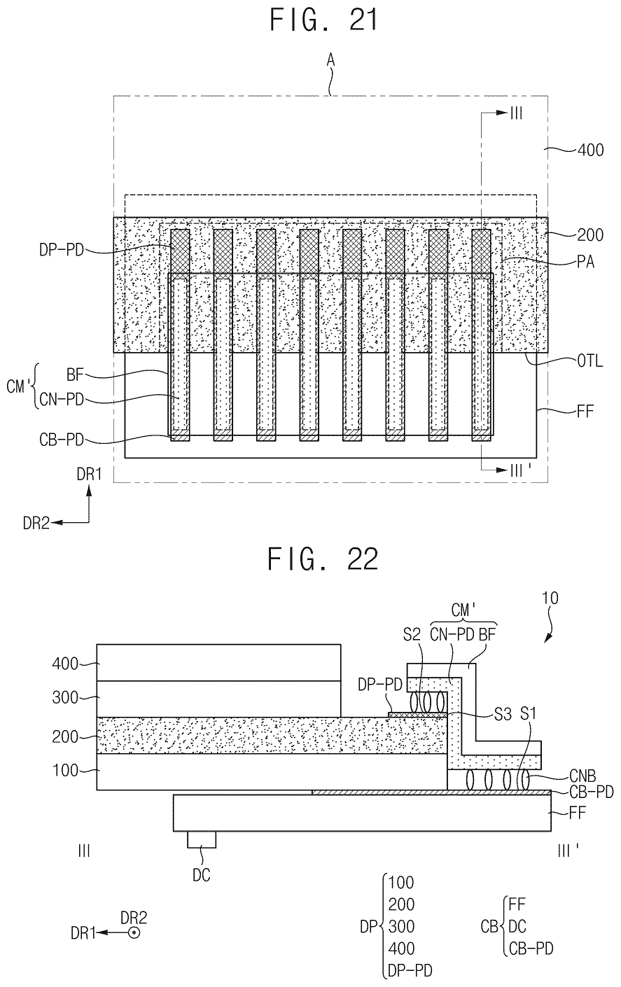

FIG. 21 is an enlarged view of area A of FIG. 3 according to an embodiment, and FIG. 22 is a cross-sectional view taken along line III-III′ of FIG. 21. The enlarged view of FIG. 21 may correspond to the enlarged view of FIG. 5.

An embodiment of the display device 10 described with reference to FIGS. 21 and 22 may be substantially same as an embodiment of the display device 10 described with reference to FIGS. 3 to 5 and 7. In some examples, the display device 10 described with reference to FIGS. 21 and 22 may differ from the display device 10 described with reference to FIGS. 3 to 5 and 7 in that the connection member is in a form of a substrate on which a pad is disposed. Accordingly, for example, descriptions of overlapping components may be replaced with the descriptions referring to FIGS. 3 to 5 and 7.

In an embodiment, the display device 10 may include a connection member CM′ that electrically connects the panel pad part DP-PD and the circuit pad part CB-PD. For example, the panel pad part DP-PD and the circuit pad part CB-PD may be electrically and physically connected through the connection member CM′.

The connection member CM′ may be disposed on the panel pad part DP-PD and the circuit pad part CB-PD. For example, embodiments of the present disclosure may include forming the connection member CM′ by pressing a conductive material on (or against) the panel pad part DP-PD and the circuit pad part CB-PD. The connection member CM′ may include a base film BF and a connection pad part CN-PD.

The base film BF may include an insulating material. In an example, the base film BF may be formed of a flexible material, and at least a portion of the base film BF may be flexible and supportive of bending. The connection pad part CN-PD may be disposed on the base film BF.

In an embodiment, the connection member CM′ may include a plurality of connection pad parts arranged along the second direction DR2. For example, the plurality of connection pad parts may correspond to the plurality of panel pad parts on a one-to-one basis. In some aspects, the plurality of connection pad parts may correspond to the plurality of circuit pad parts on a one-to-one basis. In other words, any one of the plurality of connection pad parts may electrically connect a corresponding panel pad part to a corresponding circuit pad part. However, embodiments supported by the present disclosure are not necessarily limited thereto.

In an embodiment, one end of the connection pad part CN-PD may be bonded to the upper surface S2 of the panel pad part DP-PD, and another end of the connection pad part CN-PD may be bonded to the upper surface S1 of the circuit pad part CB-PD. That is, in a plan view, at least a portion of the circuit pad part CB-PD may be exposed from the display panel DP, and the panel pad part DP-PD and the circuit pad part CB-PD may be electrically connected through the connection pad part CN-PD located on a front of the panel pad part DP-PD and the circuit pad part CB-PD. In other words, as at least a portion of the circuit pad part CB-PD is exposed from the display panel DP in a plan view, embodiments of the present disclosure may support performing a front bonding process for the panel pad part DP-PD and the circuit board CB. The connection pad part CN-PD may include a conductive material such as, for example, metal.

The connection pad part CN-PD may extend along a side surface S3 of the panel pad part DP-PD. Specifically, for example, the connection pad part CN-PD may extend from the upper surface S2 of the panel pad part DP-PD to the upper surface S1 of the circuit pad part CB-PD along the side surface S3 of the panel pad part DP-PD. In other words, the connection pad part CN-PD may be disposed on the upper surface S2 of the panel pad part DP-PD, the side surface S3 of the panel pad part DP-PD, and the upper surface S1 of the circuit pad part CB-PD. In some embodiments, the connection pad part CN-PD may be disposed such that the connection pad part CN-PD is not on the lower surface of the display panel DP.

In an embodiment, the conductive ball CNB may be disposed between the panel pad part DP-PD and the connection pad part CN-PD and between the circuit pad part CB-PD and the connection pad part CN-PD. For example, embodiments of the present disclosure support bonding the panel pad part DP-PD and the one end of the connection pad part CN-PD through the conductive ball CNB, and in some aspects, bonding the circuit pad part CB-PD and the other end of the connection pad part CN-PD through the conductive ball CNB. However, embodiments supported by the present disclosure are not necessarily limited thereto, and in some examples, the conductive ball CNB may be omitted.

In an embodiment in which the display device 10 includes the connection member CM′, the protection member PM described with reference to FIG. 6 may be omitted.

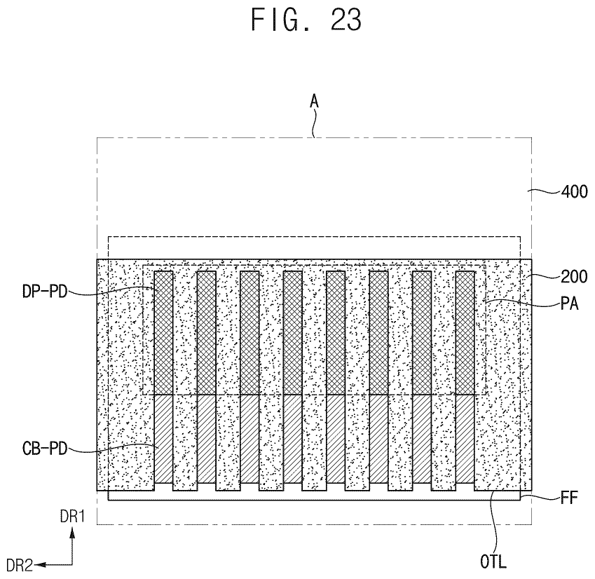

FIGS. 23 to 26 are enlarged views of area A of FIG. 3 according to other embodiments. The enlarged views of FIGS. 23 to 26 may correspond to the enlarged view of FIG. 5. For convenience of explanation, the connection member (CM, see in FIG. 5) is omitted in FIGS. 23 to 26.

The various embodiments of the display device 10 described with reference to FIGS. 23 to 26 may be substantially the same as the embodiment of the display device 10 described with reference to FIGS. 3 to 6 except for one or more features described herein. In some examples, the display device 10 described with reference to FIGS. 23 to 26 may differ from the display device 10 described with reference to FIGS. 3 to 6 in view of a planar shape of the portion of the outline OTL located on the circuit board CB. Accordingly, for example, descriptions of overlapping components may be replaced with the descriptions referring to FIGS. 3 to 6.

For example, embodiments of the present disclosure support implementing various planar shapes of the portion of the outline OTL located on the circuit board CB described with reference to FIGS. 23 to 26 by modifying or changing the cutting line which will be irradiated with the laser LB in association with the cutting process of the display panel DP as described herein.

Referring to FIG. 23, in an embodiment, the portion of the outline OTL located on the circuit board CB may have a concave-convex shape in a plan view. For example, a portion of the outline OTL defined by the side surface of the transistor layer 200 on the circuit board CB and a portion of the outline OTL defined by the side surface (S3, see in FIG. 6) of the panel pad part DP-PD on the circuit board CB may not be aligned in a straight line. Expressed another way, portions of the outline OTL may be offset from (e.g., higher than, lower than) second portions of the outline OTL in the first direction. Accordingly, for example, the portion of the outline OTL located on the circuit board CB may have a concave-convex shape having concave portions and convex portions in a plan view.

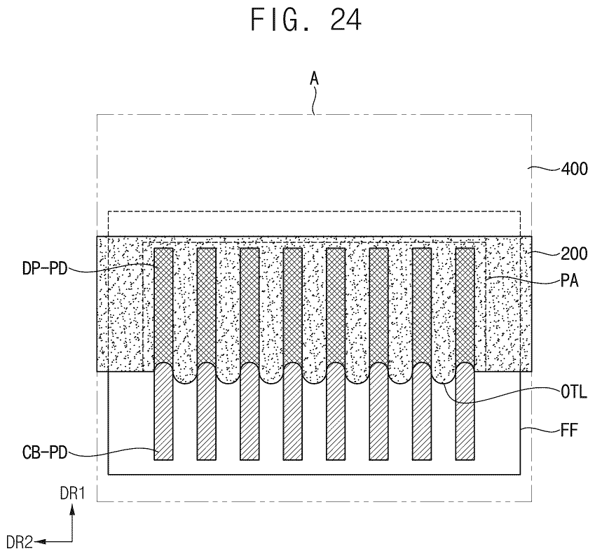

Referring to FIG. 24, in an embodiment, the portion of the outline OTL located on the circuit board CB may have a curved shape in a plan view. For example, the portion of the outline OTL located on the circuit board CB may have a shape in which a curved portion protruding in the first direction DR1 and a curved portion protruding in a direction opposite to the first direction DR1 are repeated. For example, the curved portion protruding in the first direction DR1 may be defined from the side surface (S3, see in FIG. 6) of the panel pad part DP-PD on the circuit board CB, and the curved portion protruding in the direction opposite to the first direction DR1 may be defined from the side surface of the transistor layer 200 on the circuit board CB. However, embodiments supported by the present disclosure are not necessarily limited thereto.

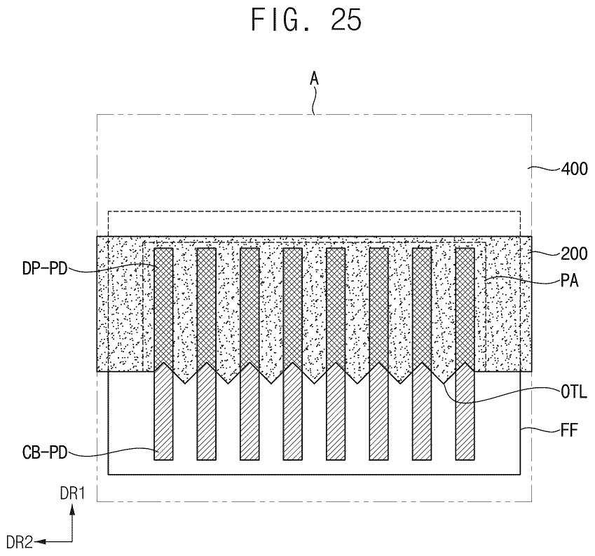

Referring to FIG. 25, in an embodiment, the portion of the outline OTL located on the circuit board CB may have a zigzag shape in a plan view. For example, the portion of the outline OTL located on the circuit board CB may have a shape in which an oblique portion protruding in the first direction DR1 and an oblique portion protruding in a direction opposite to the first direction DR1 are repeated. For example, the oblique portion protruding in the first direction DR1 may be defined from the side surface (S3, see in FIG. 6) of the panel pad part DP-PD on the circuit board CB, and the oblique portion protruding in the direction opposite to the first direction DR1 may be defined from the side surface of the transistor layer 200 on the circuit board CB. However, embodiments supported by the present disclosure are not necessarily limited thereto.

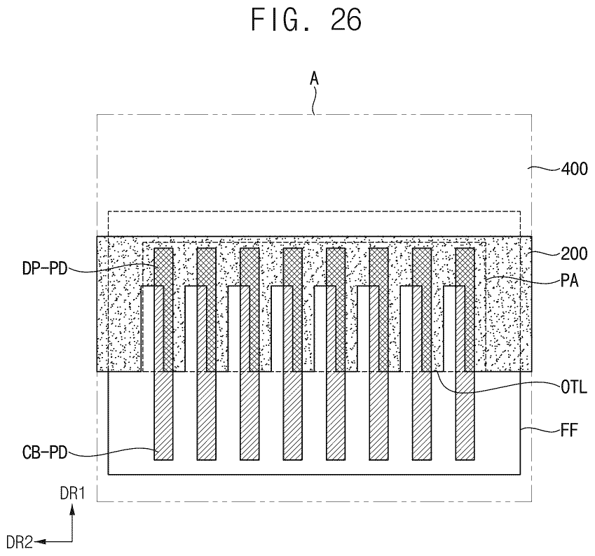

Referring to FIG. 26, in an embodiment, the portion of the outline OTL located on the circuit board CB may have a concave-convex shape in a plan view. For example, a portion of the panel pad part DP-PD may be cut such that the panel pad part DP-PD has a hammer shape in a plan view. Accordingly, for example, the portion of the outline OTL located on the circuit board CB may have a concave-convex shape having concave portions and convex portions in a plan view.

According to one or more embodiments of the present disclosure, a planar shape of the portion of the outline OTL located on the circuit board CB is not limited to the shapes illustrated in FIGS. 5 and 23 to 26 and may be variously changed according to embodiments.

The present disclosure can be applied to a display panel inspection device of various display devices. For example, the present disclosure is applicable to a display panel inspection device of various display devices such as, for example, display devices for vehicles, ships and aircraft, portable communication devices, display devices for exhibition or information transmission, medical display devices, and the like.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually equal (e.g., within a threshold percent of equal). The term “substantially simultaneously,” as used herein, means approximately or actually at the same time (e.g., within a threshold percent of equal). The term “substantially the same,” as used herein, means approximately or actually the same (e.g., within a threshold difference amount).

Spatially relative terms, such as, for example, “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

The foregoing is illustrative of example embodiments and is not to be construed as limiting thereof. Although some embodiments have been described, those skilled in the art will readily appreciate that many modifications are possible in the embodiments without materially departing from the novel teachings and advantages of aspects and features supported by the present disclosure. Accordingly, for example, all such modifications are intended to be included within the scope of the aspects and features supported by the present disclosure as defined in the claims. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A display device comprising:
a display panel comprising a panel pad part;
a circuit board below the display panel and comprising a circuit pad part, wherein the circuit pad part is at least partially exposed from the display panel in a plan view; and
a connection member which electrically connects the panel pad part and the circuit pad part.

2. The display device of claim 1, wherein one end of the connection member is bonded to an upper surface of the panel pad part, and another end of the connection member is bonded to an upper surface of a portion of the circuit pad part exposed from the display panel.

3. The display device of claim 2, wherein the connection member extends from the upper surface of the panel pad part to the upper surface of the circuit pad part along a side surface of the panel pad part.

4. The display device of claim 3, wherein the side surface of the panel pad part defines a portion of an outline of the display panel in a plan view.

5. The display device of claim 4, wherein the portion of the outline located on the circuit board has a straight shape, a curved shape, a concave-convex shape, or a zigzag shape in the plan view.

6. The display device of claim 1, wherein the connection member is not disposed on a lower surface of the display panel.

7. The display device of claim 1, wherein the connection member comprises a conductive material.

8. The display device of claim 1, wherein at least a portion of the circuit pad part overlaps the display panel in a plan view.

9. The display device of claim 1, wherein the circuit pad part is attached to a lower surface of the display panel.

10. The display device of claim 1, wherein the circuit pad part is located below the panel pad part.

11. The display device of claim 10, wherein at least a portion of the circuit pad part is exposed from the panel pad part in a plan view.

12. The display device of claim 10, wherein at least a portion of the circuit pad part overlaps the panel pad part in a plan view.

13. The display device of claim 1, further comprising:
a protection member disposed on the connection member and covering at least a portion of the connection member.

14. The display device of claim 1, wherein the circuit board comprises:
a flexible film on which the circuit pad part is disposed; and
a driving chip mounted on the flexible film.

15. A method of manufacturing a display device, the method comprising:
cutting a portion of a display panel comprising a panel pad part by irradiating the display panel with a laser based on a cutting line; and
forming a connection member comprising:
an end bonded to an upper surface of the panel pad part; and
another end bonded to an upper surface of a circuit pad part below the display panel, wherein the circuit pad part is at least partially exposed from the display panel.

16. The method of claim 15, wherein the cutting the portion of the display panel comprises cutting a portion of the panel pad part.

17. The method of claim 16, wherein:
at least a side surface of the panel pad part is defined by the cutting of the portion of the panel pad part; and
the forming of the connection member comprises forming the connection member such that the connection member extends along the side surface of the panel pad part.

18. The method of claim 15, wherein the connection member is formed of a conductive material.

19. The method of claim 15, further comprising:
attaching a circuit board comprising the circuit pad part to the display panel, below the display panel,
wherein the attaching of the circuit board is performed before the forming of the connection member.

20. The method of claim 19, wherein a portion of an outline located on the circuit board has a straight shape, a curved shape, a concave-convex shape, or a zigzag shape in a plan view, wherein the portion of the outline corresponds to a portion of the cutting line.
